(19) United States
(12) Patent Application Publication
(10) Pub. No.: US 2007/0020959 A1
(43) Pub. Date: Jan. 25, 2007

(54) Circuit board including jacks

(75) Inventors: Toshihiko Sasaki, Echizen-shi (JP); Toshio Ishimoto, Echizen-shi (JP); Masayoshi Terashima, Echizen-shi (JP); Naofumi Okayama, Echizen-shi (JP)

Correspondence Address: REED SMITH LLP;Suite 1400, 3110 Fairview Park Drive, Fall Church, VA, 22042, US

(73) Assignee: Orion Electric Company Ltd.

(21) Appl. No.: 11/486,027

(22) Filed: Jul. 14, 2006

(30) Foreign Application Priority Data
Jul. 20, 2005 (JP) 2005-209595

(51) Int. Cl. H05K 1/00

(52) U.S. Cl. 439/55

(57) ABSTRACT

A plurality of jacks are a video signal jack, a left audio signal jack, and a right audio signal jack from left to right. Jack fixing protrusions are formed on a surface of each jack which surface is attached to a circuit board. The jack fixing protrusions are arranged differently among the respective jacks, and can be inserted only into attachment portions of the circuit board corresponding to the respective jacks. Namely, insertion of the respective jacks into incorrect attachment portions is made physically impossible, and erroneous insertion of the jacks can be prevented.

### BACKGROUND OF THE INVENTION

1. Field of the Invention

The present invention relates to a circuit board including a plurality of jacks for connecting three cables to an electronic apparatus if the cables are to be connected to the electronic apparatus and different signals are transmitted through the respective cables. More specifically, the present invention relates to a circuit board including a plurality of jacks for connecting three cables to an audiovisual apparatus for separately transmitting a video signal, a left audio signal, and a right audio signal through the respective cables.

2. Description of the Related Art

There are known pin jacks as jacks frequently used when three types of signals, i.e., a video signal, a left audio signal, and a right audio signal are transmitted through different cables, respectively, in an audiovisual apparatus. These jacks are equal in external shape, irrespective of the types of the signals to be transmitted. The signal types are discriminated according to colors given to the respective jacks, and the jacks are aligned in a fixed order. FIG. 5 is a front view of television receiver. In FIG. 5, a video signal jack 1, a left audio signal jack 2, and a right audio signal jack 3 are arranged on a front surface of the television receiver from left to right in this order and colored yellow, white, and red, respectively.

In a process for manufacturing the audiovisual apparatus including these three jacks, it is required to attach the video signal jack 1 (colored yellow), the left audio signal jack 2 (colored white), and the right audio signal jack 3 (colored red) onto a circuit board 4 from left to right exactly in this order.

However, as shown in FIGS. 3 and 4, these conventional three jacks are all equal in an external shape of a housing. In addition, insertion holes provided in the circuit board 4 to which these jacks are to be attached are arranged equally. Due to this, there is a probability that the jacks are attached to incorrect attachment positions on the circuit board 4.

Japanese Patent Application Laid-Open No. 10-65290 discloses a technique for preventing erroneous insertion of jacks by silk-printing characters (e.g., “RED” for the right audio signal jack) that indicate the colors given to discriminate the types of the signals corresponding to the respective jacks to portions near the attachment portions of the circuit board 4.

Despite use of the technique disclosed in Japanese Patent Application Laid-Open No. 10-65290, the three jacks tend to be inserted into the incorrect attachment portions since they are equal in the external shape of the housing, and the insertion holes provided in the circuit board 4 to which the jacks are attached, respectively are arranged equally. Therefore, the probability of the erroneous insertion remains unsolved.

### SUMMARY OF THE INVENTION

The present invention has been achieved to solve the above-described conventional disadvantages. It is an object of the present invention to make it physically impossible to insert three jacks into incorrect attachment portions and to thereby prevent erroneous insertion of the jacks by differently arranging protrusions formed on surfaces of the respective jacks to be inserted into a circuit board.

According to a first aspect of the present invention, there is provided a circuit board including a plurality of jacks, the plurality of jacks having housings of a common shape, respectively, the plurality of jacks being uniformly assembled into the circuit board adjacently and being fitted into the circuit board, thereby positioning the plurality of jacks, wherein a plurality of positioning protrusions are formed in each of the housings of the respective jacks, insertion holes into which the plurality of positioning protrusions are fitted, respectively, are formed in the circuit board, and the positioning protrusions inserted into the circuit board are arranged differently among the respective jacks.

The circuit board including the jacks according to the first aspect of the present invention makes it physically impossible to insert the respective jacks into the incorrect attachment portions and can thereby prevent the erroneous insertion of the jacks.

According to a second aspect of the present invention, there is provided the circuit board including the plurality of jacks according to the first aspect, wherein the plurality of jacks for transmitting three signals through different cables are attached to the circuit board while aligning the plurality of jacks in an equal direction, the plurality of jacks are a first jack, a second jack, and a third jack, the first jack being attached to a left side relative to a front direction in which direction the plurality of jacks are assembled into the circuit board, the second jack being attached to a center relative to the front direction, the third jack being attached to a right side relative to the front direction, the positioning protrusions are a pair of left and right protrusions formed at each of the first, the second, and the third jacks, the left and right protrusions formed at the second jack arranged at the center are linearly symmetric about a perpendicular, and the left and right protrusions formed at each of the first and the third jacks arranged on both sides of the second jack, respectively are formed asymmetric about a perpendicular.

The circuit board including jacks according to the second aspect of the present invention makes it physically impossible to insert the respective jacks into the incorrect attachment portions and can thereby prevent the erroneous insertion of the jacks. In addition, by checking arrangement of the protrusions of the respective jacks, it is possible to easily grasp at which position (a central position or a position other than the central position) in an array of the jacks each jack is arranged.

According to a third aspect of the present invention, there is provided the circuit board including the plurality of jacks according to the second aspect, wherein the protrusions formed at a near side to the second jack at each of the first and the third jacks arranged on both sides of the second jack, respectively are provided with outward deviation.

The circuit board including jacks according to the third aspect of the present invention makes it physically impossible to insert the respective jacks into the incorrect attachment portions and can thereby prevent the erroneous insertion of the jacks. In addition, by checking arrangement of the protrusions of the respective jacks, it is possible to easily grasp in which position (a left position, a central position, or a right position) in the array of the jacks each jack is arranged.

The present invention makes it physically impossible to insert the three jacks into the incorrect attachment portions, and can thereby prevent the erroneous insertion of the jacks by differently arranging the protrusions formed on the surfaces of the respective jacks to be inserted into the circuit board.

### BRIEF DESCRIPTION OF THE DRAWINGS

FIG. 1 shows a plurality of jacks according to an embodiment of the present invention;

FIG. 2 shows a circuit board according to the embodiment of the present invention;

FIG. 3 shows a plurality of conventional jacks;

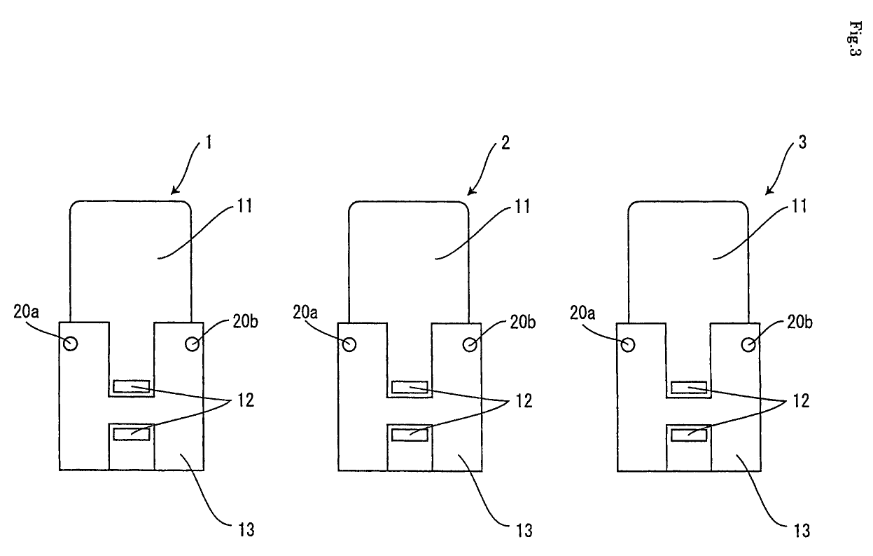

FIG. 4 shows a conventional circuit board;

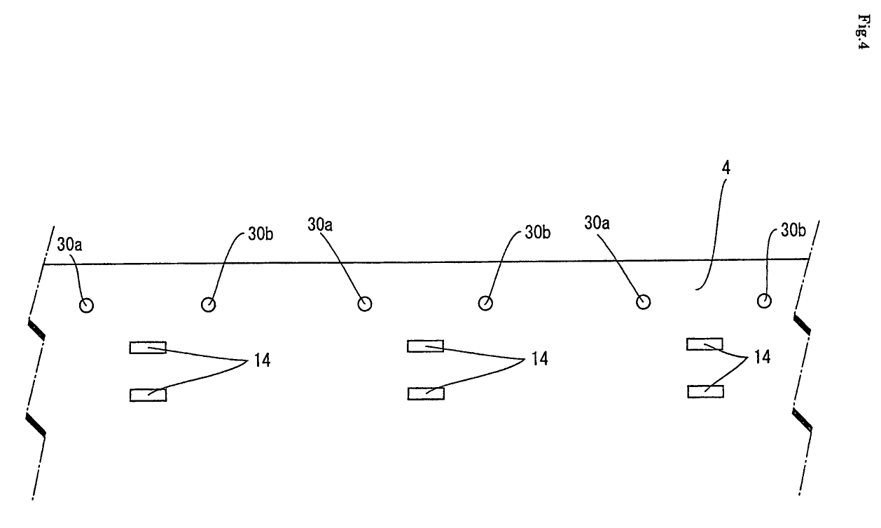

FIG. 5 is a front view of a television receiver; and

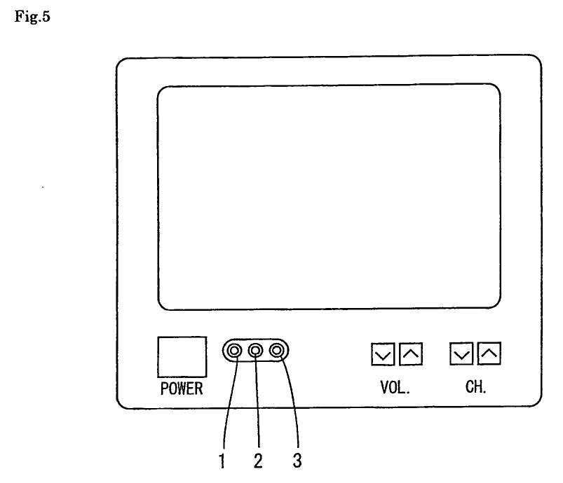

FIG. 6 is a perspective view of a circuit board into which the jacks are inserted.

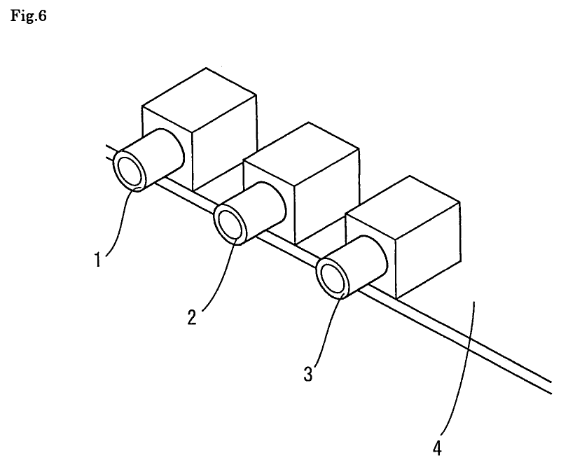

### DESCRIPTION OF THE PREFERRED EMBODIMENT

An embodiment of the present invention will be described hereinafter with reference to the drawings. It should be noted that the following embodiment is only one implemental example of the present invention and does not limit the present invention.

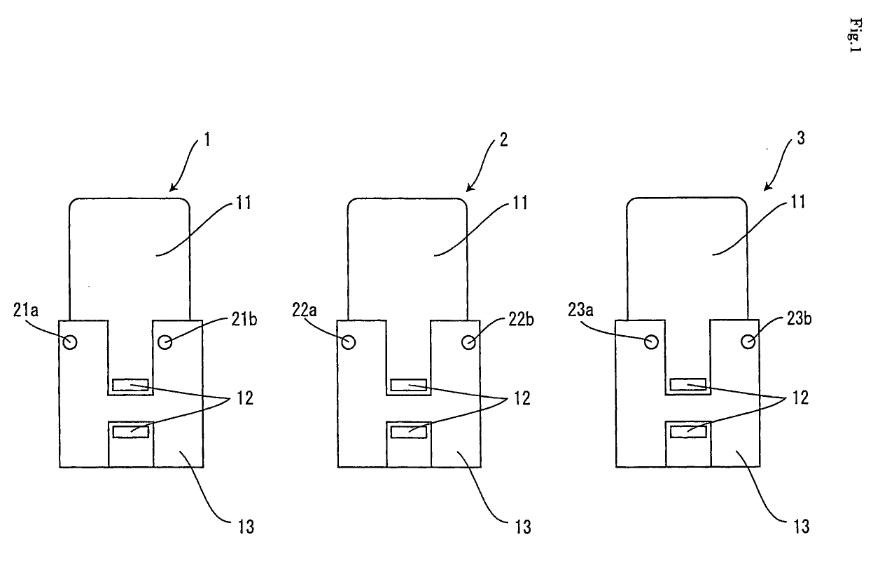

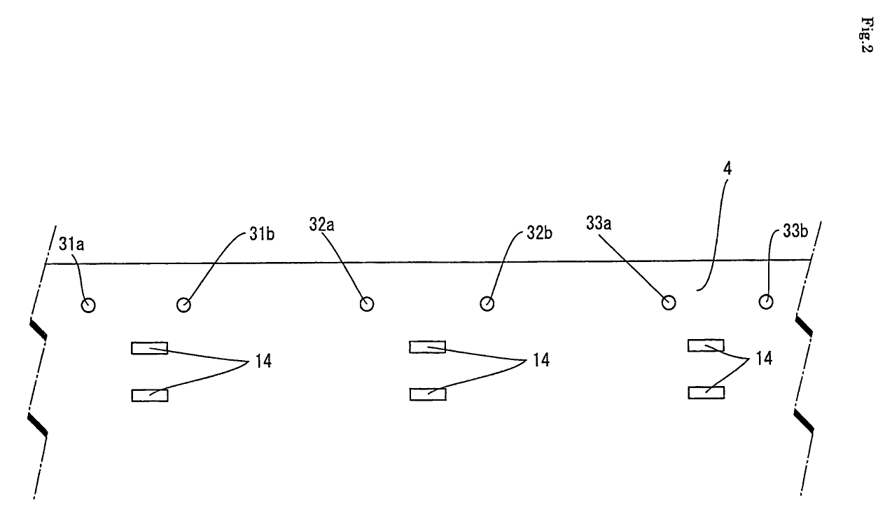

FIG. 1 shows a plurality of jacks according to one embodiment of the present invention. FIG. 2 shows a circuit board 4 to which the jacks shown in FIG. 1 are attached.

Referring to FIG. 1, the jacks are a video signal jack 1, a left audio signal jack 2, and a right audio signal jack 3 from left to right. Each of a cable connection terminal 11 and circuit board connection terminals 12 consists of a conductive material (e.g., a conductive metal), and a to-be-transmitted signal (an electric signal) passes through the terminals 11 and 12. A housing 13, which consists of an insulator, covers up an exterior of each jack. Jack fixing protrusions 21a and 21b, 22a and 22b, and 23a and 23b are protrusions formed on surfaces of the respective jacks 1, 2, and 3, which surfaces are to be attached to the circuit board 4.

Referring to FIG. 2, circuit board connection terminal insertion holes 14, and jack fixing protrusion insertion holes 31a and 31b, 32a and 32b, and 33a and 33b are provided in the circuit board 4. The circuit board connection terminals 12 are inserted into the circuit board connection terminal insertion holes 14, respectively, and soldered to the circuit board 4. The jack fixing protrusions 21a and 21b, 22a and 22b, and 23a and 23b are inserted into the jack fixing protrusion insertion holes 31a and 31b, 32a and 32b, and 33a and 33b, respectively. The jacks 1, 2, and 3 are thereby fixed to the circuit board 4.

As can be seen from FIGS. 1 and 2, the jack fixing protrusions 21a and 21b, 22a and 22b, and 23a and 23b are arranged differently among the jacks 1, 2, and 3. The jack fixing protrusions 21a and 21b, 22a and 22b, and 23a and 23b can be, therefore, inserted only into the portions of the circuit board 4 corresponding to the respective jacks 1, 2, and 3.

Further, the arrangement of the jack fixing protrusions 21a and 21b, 22a and 22b, and 23a and 23b formed at the jacks 1, 2, and 3 enables a user to easily grasp positions of the respective jacks 1, 2, and 3 in an array of the jacks 1, 2, and 3. Namely, if the protrusions are arranged linearly symmetrically, this arrangement indicates that the jack is the jack (left audio signal jack 2) to be arranged at a central position in the array. If the right jack fixing protrusion 21b is deviated from the protrusions of the central jack 2, this indicates that the jack is the jack (video signal jack 1) to be arranged at a left position in the array. If the left jack fixing protrusion 23a is deviated therefrom, this indicates that the jack is the jack (right audio signal jack 3) to be arranged at a right position in the array.

As stated so far, the present invention makes it physically impossible to insert the three jacks into incorrect attachment portions, and can thereby prevent the erroneous insertion of the jacks by differently arranging the protrusions formed on the surfaces of the respective jacks to be inserted into the circuit board.

What is claimed is:

1. A circuit board including a plurality of jacks, the plurality of jacks having housings of a common shape, respectively, the plurality of jacks being uniformly assembled into the circuit board adjacently and being fitted into the circuit board, thereby positioning the plurality of jacks, wherein
a plurality of positioning protrusions are formed in each of the housings of the respective jacks,
insertion holes into which the plurality of positioning protrusions are fitted, respectively, are formed in the circuit board, and
the positioning protrusions inserted into the circuit board are arranged differently among the respective jacks.

2. The circuit board including the plurality of jacks according to claim 1, wherein
the plurality of jacks for transmitting three signals through different cables are attached to the circuit board while aligning the plurality of jacks in an equal direction,
the plurality of jacks are a first jack, a second jack, and a third jack, the first jack being attached to a left side relative to a front direction in which direction the plurality of jacks are assembled into the circuit board, the second jack being attached to a center relative to the front direction, the third jack being attached to a right side relative to the front direction,
the positioning protrusions are a pair of left and right protrusions formed at each of the first, the second, and the third jacks, the left and right protrusions formed at the second jack arranged at the center are linearly symmetric about a perpendicular, and the left and right protrusions formed at each of the first and the third jacks arranged on both sides of the second jack, respectively are formed asymmetric about a perpendicular.

3. The circuit board including the plurality of jacks according to claim 2, wherein
the protrusions formed at a near side to the second jack at each of the first and the third jacks arranged on both sides of the second jack, respectively are provided with outward deviation.
